(19) United States
(12) Patent Application Publication
(10) Pub. No.: US 2009/0174462 A1
(43) Pub. Date: Jul. 9, 2009

(54) CIRCUIT BOARD ARRANGEMENTS FOR ELECTRONIC DEVICE INPUT COMPONENTS

(75) Inventors: Chad A. Bronstein, Sunnyvale, CA (US); Chris Ligtenberg, San Carlos, CA (US); Steven J. Sfarzo, Los Gatos, CA (US)

Correspondence Address: KRAMER LEVIN NAFTALIS & FRANKEL LLP, 1177 Avenue of the Americas, New York, NY, 10036, US

(73) Assignee: Apple Inc., Cupertino, CA (US)

(21) Appl. No.: 12/242,904

(22) Filed: Sep. 30, 2008

Related U.S. Application Data
(60) Provisional application No. 61/010,174, filed on Jan. 4, 2008.

(51) Int. Cl. H03K 17/96; G06F 1/16; H01S 4/00; G06F 3/041

(52) U.S. Cl. 327/517; 345/173; 29/592.1

(57) ABSTRACT

Electronic devices may be provided with one or more input components and one or more circuit boards. An input component may include sensor circuitry supported by a first circuit board and controller circuitry supported by a second circuit board. In other embodiments, the sensor circuitry may be coupled to a first portion of a first surface of a circuit board and the controller circuitry may be coupled to a second portion of the first surface of the same circuit board. The input component may be a multi-touch input component, such as a multi-touch trackpad.

### CROSS-REFERENCE TO RELATED APPLICATION

This claims the benefit of U.S. Provisional Patent Application No. 61/010,174, filed Jan. 4, 2008, which is hereby incorporated by reference herein in its entirety.

### FIELD OF THE INVENTION

This can relate to apparatus and methods for arranging circuit boards with respect to input components of electronic devices.

### BACKGROUND OF THE DISCLOSURE

Some known electronic devices (e.g., computers and telephones) include one or more internal electronic components associated with the operation of the device and a protective enclosure or housing. Typically, the housing includes one or more housing components that serve to surround the internal electronic components at a peripheral region of the electronic device so as to cover and protect the internal components from adverse external conditions. The one or more internal electronic components are generally coupled to a circuit board, which can be used to mechanically support and electronically connect the one or more internal electronic components to one another. Some of these internal electronic components are associated with and coupled to additional components of the electronic device that are at least partially exposed or unprotected by the housing in order to present information to a user of the device or to receive information from a user of the device (i.e., input/output (“I/O”) components, such as display screens or trackpad sensor circuitry).

Geometric features are important to consumers of electronic devices, as these features help create the overall impression that one has of the electronic device. Therefore, the construction of and interconnections between the at least partially exposed I/O components and their associated internal electronic components and circuit boards may also be configured to form and aesthetically enhance the outward appearance and size of the electronic device.

Accordingly, what is needed are apparatus and methods for arranging circuit boards with respect to input components of electronic devices.

### SUMMARY OF THE DISCLOSURE

Apparatus and methods for arranging circuit boards with respect to input components of electronic devices are provided.

According to some embodiments of the invention, there is provided an electronic device that includes a first circuit board, a second circuit board, and a first input component. The first input component may include first sensor circuitry and first controller circuitry. The first sensor circuitry may be supported by the first circuit board, and the first controller circuitry may be supported by the second circuit board.

According to other embodiments of the invention, there is provided an electronic device that includes a first circuit board having a first surface and a first multi-touch input component having first sensor circuitry and first controller circuitry. The first sensor circuitry may be coupled to a first portion of the first surface of the first circuit board, and the first controller circuitry may be coupled to a second portion of the first surface of the first circuit board.

According to yet other embodiments of the invention, there is provided a method of manufacturing an electronic device. The method may include coupling first sensor circuitry of a multi-touch trackpad input component to a first circuit board of the electronic device. The method may also include coupling first controller circuitry of the multi-touch trackpad input component to a second circuit board of the electronic device.

### BRIEF DESCRIPTION OF THE DRAWINGS

The above and other features of the invention, its nature, and various advantages will become more apparent upon consideration of the following detailed description, taken in conjunction with the accompanying drawings, in which like reference characters refer to like parts throughout, and in which:

FIG. 1 shows a simplified schematic diagram of an electronic device, according to some embodiments of the invention;

FIG. 2 shows a top, front, right perspective view of the electronic device of FIG. 1 in an open position, according to some embodiments of the invention;

FIG. 3 shows a bottom, back, left perspective view of the electronic device of FIGS. 1 and 2 in a closed position, according to some embodiments of the invention;

FIG. 4 shows a horizontal cross-sectional view of a portion of the electronic device of FIGS. 1-3, taken from line IV-IV of FIG. 2, in accordance with some embodiments of the invention; and

FIG. 5 is a vertical cross-sectional view of a portion of the electronic device of FIGS. 1-4, taken from line V-V of FIG. 4, in accordance with some embodiments of the invention.

### DETAILED DESCRIPTION OF THE DISCLOSURE

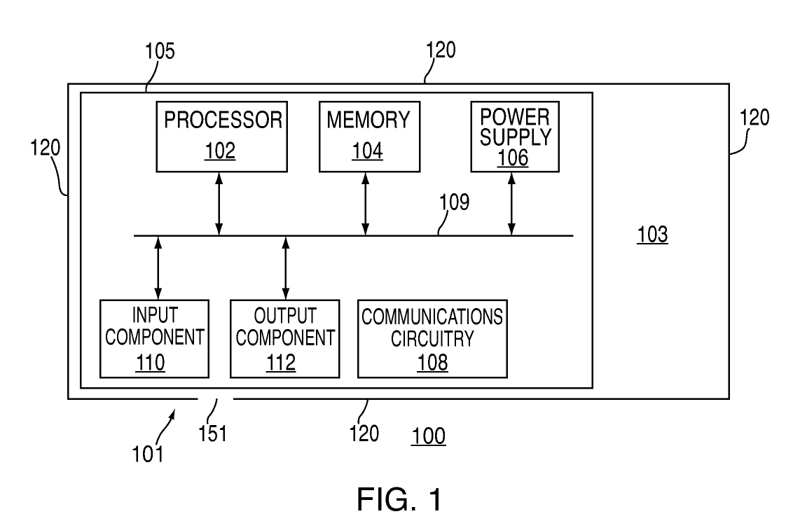

Apparatus and methods for arranging circuit boards with respect to input components of electronic devices are provided and described with reference to FIGS. 1-5.

FIGS. 1-5 illustrate an exemplary electronic device 100 constructed in accordance with some embodiments of the invention. The term “electronic device” can include, but is not limited to, music players, video players, still image players, game players, other media players, music recorders, video recorders, cameras, other media recorders, radios, medical equipment, domestic appliances, transportation vehicle instruments, calculators, cellular telephones, other wireless communication devices, personal digital assistants, programmable remote controls, pagers, laptop or notebook computers, desktop computers, printers, and combinations thereof. In some cases, the electronic device may perform a single function (e.g., a device dedicated to playing music) and, in other cases, the electronic device may perform multiple functions (e.g., a device that plays music, displays video, stores pictures, and receives and transmits telephone calls).

Moreover, in some cases, the electronic device may be any portable, mobile, hand-held, or miniature electronic device having an input component constructed according to the invention that allows a user to use the device wherever the user travels. Miniature electronic devices may have a form factor that is smaller than that of hand-held electronic devices, such as an iPod™ available by Apple Inc. of Cupertino, Calif. Illustrative miniature electronic devices can be integrated into various objects that include, but are not limited to, watches, rings, necklaces, belts, accessories for belts, headsets, accessories for shoes, virtual reality devices, other wearable electronics, accessories for sporting equipment, accessories for fitness equipment, key chains, and combinations thereof. Alternatively, electronic devices that incorporate an input component of the invention may not be portable at all, but may instead be generally stationary, such as a desktop computer or television.

As shown in FIG. 1, electronic device 100 may include housing 101, processor 102, memory 104, motherboard 105, power supply 106, communications circuitry 108, bus 109, input component 110, and output component 112. Bus 109 may include one or more wired or wireless links that provide paths for transmitting data and/or power, to, from, or between various components of electronic device 100 including, for example, processor 102, memory 104, power supply 106, communications circuitry 108, input component 110, and output component 112.

Memory 104 may include one or more storage mediums, including, but not limited to, a hard-drive, flash memory, permanent memory such as read-only memory (“ROM”), semi-permanent memory such as random access memory (“RAM”), any other suitable type of storage component, and any combinations thereof. Memory 104 may include cache memory, which may be one or more different types of memory used for temporarily storing data for electronic device applications.

Power supply 106 may provide power to the electronic components of electronic device 100. In some embodiments, power supply 106 can be coupled to a power grid (e.g., when device 100 is not a portable device, such as a desktop computer). In some embodiments, power supply 106 can include one or more batteries for providing power (e.g., when device 100 is a portable device, such as a cellular telephone or a laptop computer). As another example, power supply 106 can be configured to generate power from a natural source (e.g., solar power using solar cells).

Communications circuitry 108 may be provided to allow device 100 to communicate with one or more other electronic devices or various other components using any suitable communications protocol. For example, communications circuitry 108 may support Wi-Fi™ (e.g., an 802.11 protocol), Ethernet, Bluetooth™, high frequency systems (e.g., 900 MHz, 2.4 GHz, and 5.6 GHz communication systems), infrared, transmission control protocol/internet protocol (“TCP/IP”) (e.g., any of the protocols used in each of the TCP/IP layers), hypertext transfer protocol (“HTTP”), BitTorrent™, file transfer protocol (“FTP”), real-time transport protocol (“RTP”), real-time streaming protocol (“RTSP”), secure shell protocol (“SSH”), any other communications protocol, and any combinations thereof. Communications circuitry 108 can also include circuitry that enables device 100 to be electrically coupled to another device (e.g., a computer or an accessory device) and communicate with that other device.

One or more input components 110 may be provided to permit a user to interact or interface with device 100. For example, input component 110 can take a variety of forms, including, but not limited to, an electronic device pad, dial, click wheel, scroll wheel, touch screen, one or more buttons (e.g., a keyboard), mouse, joy stick, track ball, microphone, camera, video recorder, and any combinations thereof. Input component 110 may include a multi-touch trackpad or screen, such as that described in Westerman et al. U.S. Pat. No. 6,323,846, which is incorporated by reference herein in its entirety. Input component 110 may emulate a rotary phone or a multi-button electronic device pad, which may be implemented on a touch screen or the combination of a click wheel or other user input device and a screen. Each input component 110 may be configured to provide one or more dedicated control functions for making selections or issuing commands associated with operating device 100.

One or more output components 112 can be provided to present information (e.g., textual, graphical, audible, and/or tactile information) to a user of device 100. Output component 112 can take a variety of forms, including, but not limited to, audio speakers, headphones, signal line-outs, visual displays, antennas, infrared ports, rumblers, vibrators, and any combinations thereof.

It should be noted that one or more input components 110 and/or one or more output components 112 may sometimes be referred to individually or collectively herein as an input/output (“I/O”) component or I/O or user interface. It should also be noted that one or more input components 110 and one or more output components 112 may sometimes be combined to provide a single I/O component or user interface, such as a touch screen that may receive input information through a user's touch of a display screen and that may also provide visual information to a user via that same display screen.

Processor 102 of device 100 may control the operation of many functions and other circuitry provided by device 100. For example, processor 102 can receive input signals from input component 110 and/or drive output signals through output component 112. Processor 102 may load a user interface program (e.g., a program stored in memory 104 or on another device or server) to determine how instructions received via input component 110 may manipulate the way in which information (e.g., information stored in memory 104 or on another device or server) is provided to the user via output component 112.

Motherboard 105 may be a central or primary printed circuit board (“PCB”) of electronic device 100, and may also be known as a main circuit board, mainboard, baseboard, system board, planar board, or logic board. Motherboard 105 may provide attachment points for one or more of the other electronic components of electronic device 100 (e.g., processor 102, memory 104, power supply 106, communications circuitry 108, input component 110, output component 112, any external peripheral devices, etc.). Generally, most of the basic circuitry and components required for electronic device 100 to function may be onboard or coupled (e.g., via a cable) to motherboard 105. Motherboard 105 may include one or more chipsets or specialized groups of integrated circuits. For example, motherboard 105 may include two components or chips, such as a Northbridge and Southbridge. Although in other embodiments, these chips may be combined into a single component.

Electronic device 100 may include multiple circuit boards 105, and each circuit board may be electrically coupled to one another in various ways (e.g., via cables). One or more of the electronic components of electronic device 100 may be coupled to one or more of these circuit boards, which can be used to mechanically support and electronically connect the one or more internal electronic components to one another. Some of these internal electronic components may be associated with and coupled to additional components of the electronic device that are at least partially exposed or unprotected by the housing in order to present information to a user of the device and/or to receive information from a user of the device. For example, input component 110 may include at least one partially exposed user element with which a user may physically interact, as well as at least one internal electronic component coupled to the user element. The internal electronic component may detect the user's physical interaction with the exposed user element and translate that interaction into information that can be used to affect the operation of the device.

Therefore, housing 101 may at least partially enclose one or more of the various electronic components associated with operating electronic device 100 for protecting them from debris and other degrading forces external to device 100. In some embodiments, housing 101 may include one or more walls 120 that define a cavity 103 within which the various electronic components of device 100 can be disposed. In some embodiments, housing 101 can support various electronic components of device 100, such as I/O component 110 and/or I/O component 112, at the surfaces or within one or more housing openings 151 through the surfaces of walls 120 of housing 101. Housing openings 151 may also allow certain fluids (e.g., air) to be drawn into and discharged from cavity 103 of electronic device 100 for helping to manage the internal temperature of device 100.

In some embodiments, one or more of the electronic components of electronic device 100 may be provided within its own housing component (e.g., input component 110 may be an independent keyboard or mouse within its own housing component that may wirelessly or through a wire communicate with processor 102, which may similarly be provided within its own housing component). Housing 101 can be formed from a wide variety of materials including, but not limited to, metals (e.g., steel, copper, titanium, aluminum, and various metal alloys), ceramics, plastics, and any combinations thereof. Housing 101 may also help to define the shape or form of electronic device 100. That is, the contour of housing 101 may embody the outward physical appearance of electronic device 100.

A disadvantage of some conventional electronic devices is that the reduction of their size can be limited by a certain input component construction that has its exposed user element or elements coupled to a first side of a circuit board (e.g., a printed circuit board) and its associated internal electronic component or components coupled to a second side of the same circuit board. According to some embodiments of the invention, rather than stacking the various portions of an input component on different sides (e.g., opposite sides) of a single circuit board, the thickness of an electronic device input component may be reduced by coupling the various portions of the input component to different circuit boards or to different portions of a single surface of a single circuit board. Moreover, according to some embodiments of the invention, rather than coupling the various portions of an input component to different sides (e.g., opposite sides) of a single circuit board by using one or more vias running downwardly through the circuit board, one or more vias may run laterally from one portion of an electronic device input component on a first circuit board to another portion of the input component, which may be positioned on a second circuit board or positioned laterally next to the first portion of the input component on the same first circuit board, for example.

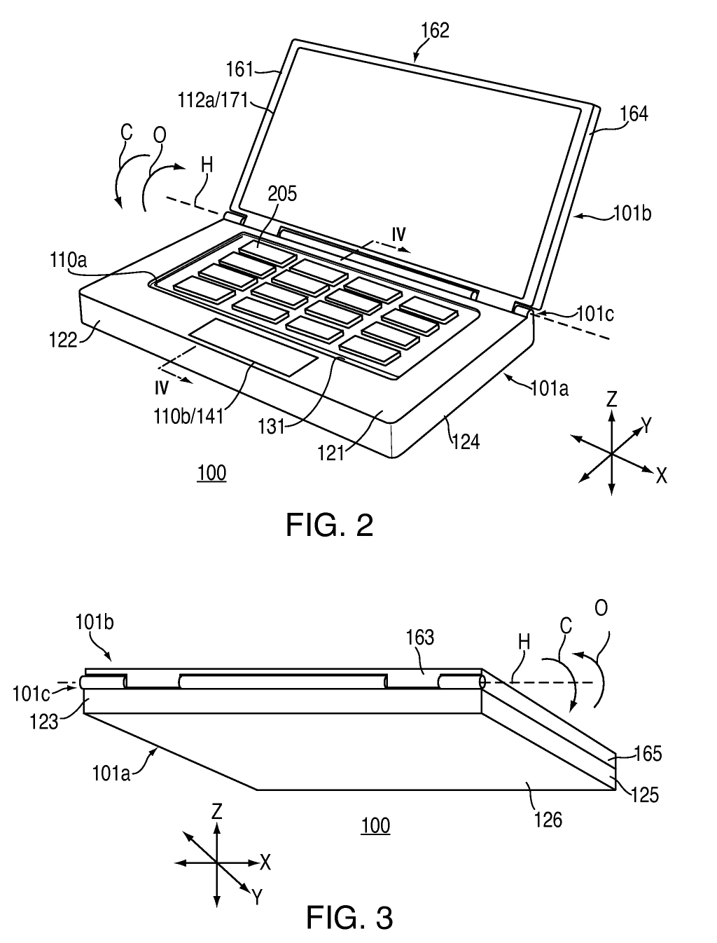

Electronic device 100 is illustrated in FIGS. 2-5 to be a laptop or notebook computer, although it is to be understood that electronic device 100 may be any type of electronic device as described herein in accordance with the invention. As shown in FIGS. 2 and 3, for example, housing 101 of electronic device 100 may be configured to provide two housing components coupled together by a hinge or clutch assembly. Particularly, housing 101 may include a base housing component 101a and a display housing component 101b coupled to one another by a hinge assembly 101c, also known as clutch assembly 101c. Housing components 101a, 101b, and 101c may be configured such that electronic device 100 may be “opened” for use (see, e.g., FIG. 2) by rotating display housing component 101b away from base housing component 101a in the direction of arrow O about hinge axis H of hinge assembly 101c, and such that electronic device 100 may be “closed” (see, e.g., FIG. 3) by rotating display housing component 101b towards base housing component 101a in the direction of arrow C about hinge axis H. However, it should be noted that housing 101 of device 100 is only exemplary and need not include two substantially hexahedral portions coupled by a hinge. For example, in certain embodiments, the housing of device 100 could generally be formed in any other suitable shape, including, but not limited to, one or more housing components or portions that are substantially spherical, ellipsoidal, conoidal, octahedral, and any combinations thereof.

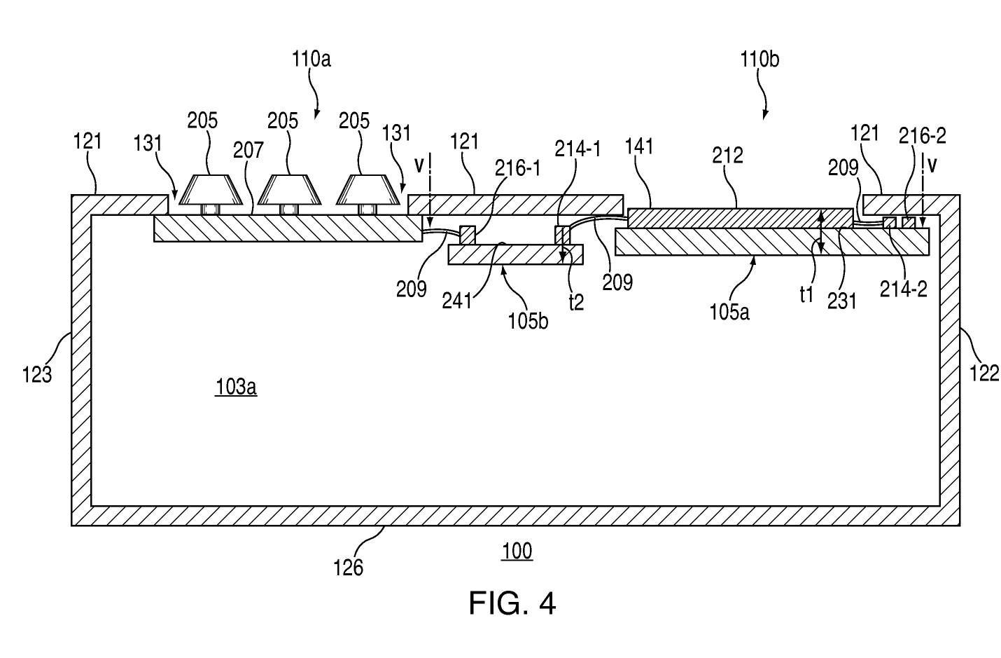

Base housing component 101a may include a top wall 121, various side walls, such as front wall 122, back wall 123, right wall 124, and left wall 125, and a bottom wall 126 opposite top wall 121. In some embodiments, one or more openings may be provided through one or more of the walls of housing component 101a to at least partially expose one or more components of electronic device 100. For example, as shown in FIGS. 2 and 4, an opening 131 may be provided through top wall 121 of base housing component 101a to at least partially expose an input component 110a of electronic device 100. In some embodiments, as shown in FIGS. 2 and 4, for example, an opening 141 may be provided through top wall 121 of base housing component 101a to at least partially expose an input component 110b of electronic device 100.

Likewise, display housing component 101b may include a top wall 161, various side walls, such as front wall 162, back wall 163, right wall 164, and left wall 165, and a bottom wall (not shown) opposite top wall 161. In some embodiments, one or more openings may be provided through one or more of the walls of housing component 101b to at least partially expose one or more components of electronic device 100. For example, as shown in FIG. 2, an opening 171 may be provided through top wall 161 of display housing component 101b to at least partially expose an output component 112a of electronic device 100.

Input component 110a is illustrated in FIGS. 2-5 to be a keyboard assembly including one or more keys 205 and one or more internal electronic components 216 coupled to keyboard circuitry 207, although it is to be understood that input component 110a exposed by opening 131 through top wall 121 of housing component 101a may be any type of component as described herein in accordance with the invention. Moreover, although input component 110b is illustrated in FIGS. 2-5 to be a trackpad assembly including sensor circuitry 212 and one or more internal electronic components 214, it is to be understood that input component 110b exposed by opening 141 through top wall 121 of housing component 101a may be any type of component as described herein in accordance with the invention. Similarly, although output component 112a is illustrated in FIG. 2 to be a visual display, it is to be understood that output component 112a exposed by opening 171 through top wall 161 of housing component 101b also may be any type of component as described herein in accordance with the invention.

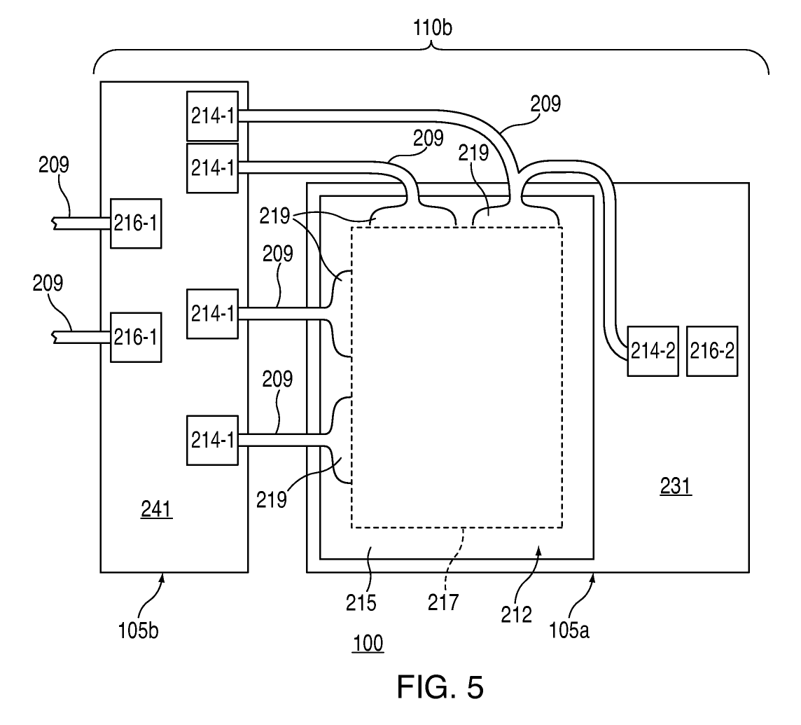

As shown in FIGS. 4 and 5, for example, trackpad input component 110b may include exposed trackpad sensor circuitry 212 (e.g., a capacitive sensor array) and one or more trackpad internal electronic components 214 (e.g., controller circuitry). Trackpad sensor circuitry 212 may be at least partially exposed to a user (not shown) through opening 141 in top wall 121 of housing component 101a. Trackpad sensor circuitry 212 may be a capacitive sensor array and may include multi-touch sensor circuitry. Trackpad sensor circuitry 212 may be coupled to a top surface 231 of a first circuit board 105a. At least one of the one or more trackpad internal electronic components 214 associated with exposed trackpad sensor circuitry 212, such as trackpad internal electronic component 214-1, may be coupled to a top surface 241 of a second circuit board 105b. Therefore, by coupling the various portions of input component 110b to respective circuit boards, rather than stacking the various portions of input component 110b on different sides (e.g., opposite sides) of a single circuit board, the maximum thickness of input component 110b may be reduced to the greater of thickness t1 created by trackpad sensor circuitry 212 stacked on top of first circuit board 105a and thickness t2 created by trackpad internal electronic component 214 stacked on top of second circuit board 105b (e.g., 0.6 millimeters).

In some embodiments, second circuit board 105b may only support one or more trackpad internal electronic components 214 that are associated with trackpad sensor circuitry 212 of input component 110b. In other embodiments, second circuit board 105b may also support portions of various other components of electronic device 100. For example, as shown in FIGS. 4 and 5, second circuit board 105b may support not only one or more trackpad internal electronic components 214, but also one or more internal electronic components 216 associated with keyboard input component 110a, such as internal electronic component 216-1 (e.g., a keyboard controller). Therefore, in some embodiments, a first input component controller (e.g., keyboard controller 216-1 of keyboard input component 110a) and a second input component controller (e.g., trackpad controller 214-1) may be combined into a single component (e.g., a single application-specific integrated circuit (“ASIC”)) on a single circuit board 105b.

Likewise, in some embodiments, first circuit board 105a may only support exposed trackpad sensor circuitry 212. In other embodiments, first circuit board 105a may support various portions of input component 110b coupled to top surface 231, such as trackpad sensor circuitry 212 and trackpad internal electronic component 214-2. Moreover, first circuit board 105a may support various portions of various other electronic components of electronic device 100. For example, first circuit board 105a may support trackpad sensor circuitry 212 of input component 110b as well as a circuitry component portion of input component 110a (e.g., internal electronic component 216-2) on its top surface 231.

First circuit board 105a may be made of any suitable material for supporting exposed trackpad sensor circuitry 212. For example, first circuit board 105a may be a flexible circuit board and may be at least partially made of a flexible high-performance plastic substrate, such as polyimide. Second circuit board 105b may also be a flexible circuit board. However, in some embodiments, when supporting one or more trackpad internal electronic components 214 as well as one or more internal electronic components associated with another functional component of device 100 (e.g., keyboard internal electronic component 216-1), for example, second circuit board 105b may be a printed circuit board and may be made of rigid material, such as copper. In other embodiments, each circuit board may be rigid or flexible.

The various portions of each input component 110 may be coupled to one another using one or more electrical links 209 (e.g., a flex cable). For example, one or more electrical links 209 may be provided for traversing the distance between first circuit board 105a and second circuit board 105b for coupling exposed trackpad sensor circuitry 212 to one or more trackpad internal electronic components 214-1. There are many advantages to laterally running electrical links from one portion 212 of input component 110b on first circuit board 105a to another portion 214-1 of input component 110b either on the same surface of first circuit board 105a or on an adjacent surface of a second circuit board 105b, rather than coupling the various portions of an input component on different sides (e.g., opposite sides) of a single circuit board by using one or more vias running downwardly through the circuit board.

For example, as opposed to running the traces from the trackpad sensor circuitry through vias running through a circuit board from a first surface to control circuitry on a second surface of the circuit board, traces of the trackpad circuitry may “fan out” laterally along the same surface of the circuit board that the trackpad sensor circuitry is coupled to. As shown in FIG. 5, for example, trackpad sensor circuitry 212 may include one or more trace fan out portions 219 where traces running across trackpad sensor circuitry 212 may be collected and routed out via one or more links 209 to one or more trackpad internal electronic components 214. Each fan out portion 219 may run along surface 231 of circuit board 105a. Trackpad sensor circuitry 212, which may be a capacitive sensor array, may have a functional area 217 and a dead band or non-functional area 215 where user inputs may not be detected. For example, non-functional area 215 may be a band of width W (e.g., 2.5 millimeters) about functional portion 217. In some embodiments, one or more fan out portions 219 may be at least partially located within non-functional area 215. In some embodiments, surface 231 of circuit board 105a and surface 241 of circuit board 105b may be co-planar, such that fan out portions 219 and links 209 may run along substantially the same plane.

While there have been described systems and methods for arranging circuit boards with respect to input components of electronic devices, it is to be understood that many changes may be made therein without departing from the spirit and scope of the invention. It is also to be understood that various directional and orientational terms such as “front” and “back” and “rear,” “left” and “right,” “top” and “bottom,” and the like are used herein only for convenience, and that no fixed or absolute directional or orientational limitations are intended by the use of these words. For example, the devices of the invention can have any desired orientation. If reoriented, different directional or orientational terms may need to be used in their description, but that will not alter their fundamental nature as within the scope and spirit of the invention. Those skilled in the art will appreciate that the invention can be practiced by other than the described embodiments, which are presented for purposes of illustration rather than of limitation, and the invention is limited only by the claims which follow.

What is claimed is:

1. An electronic device comprising:
a first circuit board;
a second circuit board; and
a first input component having first sensor circuitry and first controller circuitry, wherein the first sensor circuitry is supported by the first circuit board, and wherein the first controller circuitry is supported by the second circuit board.

2. The electronic device of claim 1, wherein the first input component is a multi-touch input component.

3. The electronic device of claim 1, wherein the first sensor circuitry is a capacitive sensor array.

4. The electronic device of claim 3, wherein the capacitive sensor array is supported by a first surface of the first circuit board, wherein an outer portion of the capacitive sensor array extends along the first surface, and wherein the outer portion includes at least one trace fan out portion of the capacitive sensor array.

5. The electronic device of claim 4, wherein the outer portion is a dead band portion of the capacitive sensor array.

6. The electronic device of claim 4, wherein the outer portion is about 2.5 millimeters wide.

7. The electronic device of claim 1, wherein the first sensor circuitry and the first controller circuitry are coupled by a flex cable.

8. The electronic device of claim 1 further comprising a second input component, wherein the second input component is at least partially supported by the second circuit board.

9. The electronic device of claim 8, wherein the second input component is a keyboard assembly.

10. The electronic device of claim 1 further comprising a second input component, wherein the second input component includes second component circuitry and second controller circuitry, and wherein the second controller circuitry is supported by the second circuit board.

11. The electronic device of claim 10, wherein the first controller circuitry and the second controller circuitry are a single application-specific integrated circuit.

12. The electronic device of claim 1, wherein the first circuit board is a flexible circuit board, and wherein the second circuit board is a rigid circuit board.

13. An electronic device comprising:
a first circuit board having a first surface; and
a first multi-touch input component having first sensor circuitry and first controller circuitry, wherein the first sensor circuitry is coupled to a first portion of the first surface of the first circuit board, and wherein the first controller circuitry is coupled to a second portion of the first surface of the first circuit board.

14. The electronic device of claim 13, wherein the first multi-touch input component is a trackpad.

15. The electronic device of claim 13, wherein the first sensor circuitry is a capacitive sensor array.

16. The electronic device of claim 15, wherein an outer portion of the capacitive sensor array extends along the first surface, and wherein the outer portion includes traces of the capacitive sensor array.

17. The electronic device of claim 16, wherein the outer portion is a dead band portion of the capacitive sensor array.

18. The electronic device of claim 13 further comprising a second input component, wherein the second input component is at least partially supported by the first circuit board.

19. The electronic device of claim 18, wherein the second input component is a keyboard assembly.

20. A method of manufacturing an electronic device, the method comprising:
coupling first sensor circuitry of a multi-touch trackpad input component to a first circuit board of the electronic device; and
coupling first controller circuitry of the multi-touch trackpad input component to a second circuit board of the electronic device.
